(19) United States
(12) Patent Application Publication
(10) Pub. No.: US 2023/0269950 A1
(43) Pub. Date: Aug. 24, 2023

(54) MAGNETIC MEMORY DEVICE

(71) Applicant: Kioxia Corporation, Tokyo (JP)

(72) Inventors: Tadaaki OIKAWA, Seoul (KR); Kenichi YOSHINO, Seongnam-si Gyeonggi-do (KR); Kazuya SAWADA, Seoul (KR); Takuya SHIMANO, Seoul (KR); Young Min EEH, Seongnam-si Gyeonggi-do (KR); Taiga ISODA, Seoul (KR)

(73) Assignee: Kioxia Corporation, Tokyo (JP)

(21) Appl. No.: 17/842,417

(22) Filed: Jun. 16, 2022

(30) Foreign Application Priority Data
Feb. 18, 2022 (JP) 2022-024004

(51) Int. Cl. H01L 27/22; H01L 43/02; G11C 11/16

(52) U.S. Cl. CPC H01L 27/224; H01L 43/02; G11C 11/161; H01L 43/10

(57) ABSTRACT

A magnetic memory device according to an embodiment includes a first ferromagnetic layer, a first nonmagnetic layer on the first ferromagnetic layer, a second ferromagnetic layer on the first nonmagnetic layer, an oxide layer on the second ferromagnetic layer, and a second nonmagnetic layer on the oxide layer. The oxide layer contains an oxide of a rare-earth element. The second nonmagnetic layer contains cobalt (Co), iron (Fe), boron (B), and molybdenum (Mo).

### CROSS-REFERENCE TO RELATED APPLICATIONS

This application is based upon and claims the benefit of priority from Japanese Patent Application No. 2022-024004, filed Feb. 18, 2022, the entire contents of which are incorporated herein by reference.

### FIELD

Embodiments described herein relate generally to a magnetic memory device.

### BACKGROUND

A memory device (magnetoresistive random access memory (MRAM)), which adopts a magnetoresistive effect element as a memory element, is known.

### BRIEF DESCRIPTION OF THE DRAWINGS

FIG. 1 is a block diagram showing a configuration example of a memory system according to an embodiment.

FIG. 2 is a circuit diagram showing an example of a circuit configuration of a memory cell array included in a magnetic memory device according to the embodiment.

FIG. 3 is a perspective view showing an example of a three-dimensional structure of the memory cell array included in the magnetic memory device according to the embodiment.

FIG. 4 is a cross-sectional diagram showing an example of a cross-sectional structure of a variable resistance element included in a memory cell of the magnetic memory device according to the embodiment.

FIG. 5 is a schematic diagram showing an example of a change in characteristics based on a difference in a stacked structure of a top layer.

FIG. 6 is a table showing an example of a change in characteristics based on a difference in material of the top layer.

FIG. 7 is a table showing examples of etching rates of materials used for the top layer.

FIG. 8 is a graph showing an example of a relationship between a content ratio of molybdenum contained in a layer of cobalt iron boron of the top layer and an etching rate.

FIG. 9 is a graph showing an example of a relationship between the content ratio of molybdenum contained in the layer of cobalt iron boron of the top layer and an anisotropic magnetic field of a storage layer.

### DETAILED DESCRIPTION

In general, according to one embodiment, a magnetic memory device includes a first ferromagnetic layer, a first nonmagnetic layer on the first ferromagnetic layer, a second ferromagnetic layer on the first nonmagnetic layer, an oxide layer on the second ferromagnetic layer, and a second nonmagnetic layer on the oxide layer. The oxide layer contains an oxide of a rare-earth element. The second nonmagnetic layer contains cobalt (Co), iron (Fe), boron (B), and molybdenum (Mo).

An embodiment will be described below with reference to the accompanying drawings. The drawings are schematic or conceptual. The dimensions, ratios, etc. in the drawings are not always the same as the actual ones. In the descriptions below, constituent elements having approximately the same function and configuration will be denoted by the same reference symbol. A numeral, etc., following letters constituting a reference symbol is used to distinguish between elements referred to by reference symbols including the same letters and having the same configuration. When elements represented by reference symbols that include the same letters need not be distinguished from one another, they are referred to by reference symbols that include only letters.

### Embodiment

Hereinafter, a memory system MS according to the embodiment will be described.

### [1] Configuration

### [1-1] Configuration of Memory System MS

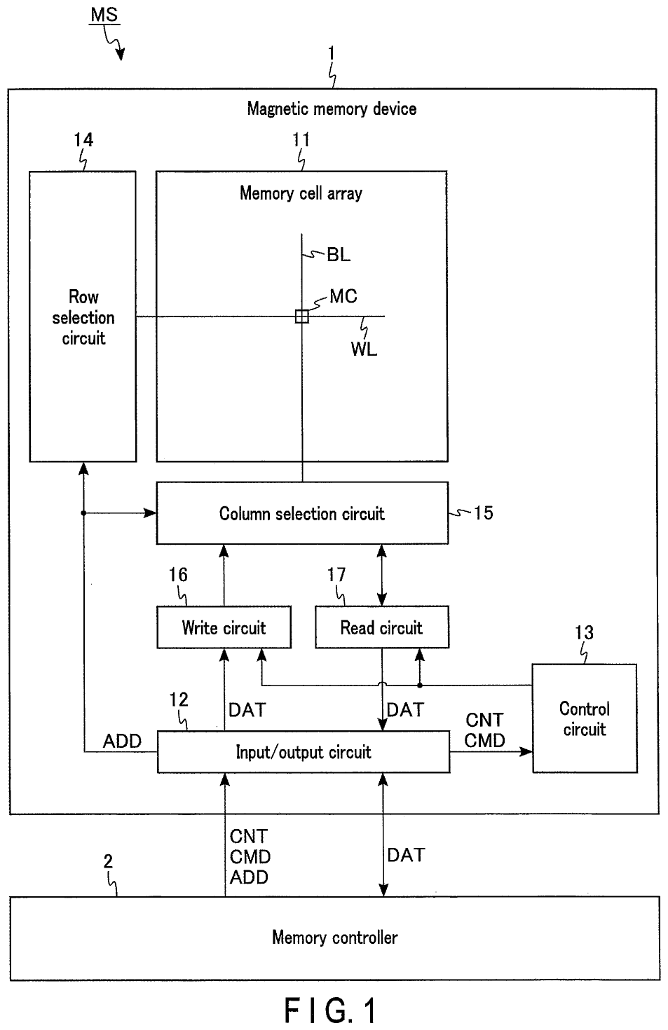

FIG. 1 is a block diagram showing a configuration example of the memory system MS according to the embodiment. As shown in FIG. 1, the memory system MS includes a magnetic memory device 1 and a memory controller 2. The magnetic memory device 1 operates based on control of the memory controller 2. The memory controller 2 may order the magnetic memory device 1 to perform a read operation, a write operation, etc., in response to a request (order) from an external host device.

The magnetic memory device 1 is a memory device using a magnetic tunnel junction (MTJ) element as a memory cell, and is a type of variable resistance memory. The MTJ element uses a magnetoresistance effect provided by a magnetic tunnel junction. The MTJ element is also referred to as a “magnetoresistance effect element”. The magnetic memory device 1 includes, for example, a memory cell array 11, an input/output circuit 12, a control circuit 13, a row selection circuit 14, a column selection circuit 15, a write circuit 16, and a read circuit 17.

The memory cell array 11 includes a plurality of memory cells MC, a plurality of word lines WL, and a plurality of bit lines BL. FIG. 1 shows a set of a memory cell MC, a word line WL, and a bit line BL. The memory cell MC may store data in a nonvolatile manner. The memory cell MC is coupled between a single word line WL and a single bit line BL, and is associated with a set of a row and a column. A row address is assigned to the word line WL. A column address is assigned to the bit line BL. One or more memory cells MC may be specified by selection of one row and selection of one or more columns.

The input/output circuit 12 is coupled to the memory controller 2, and controls communications between the magnetic memory device 1 and the memory controller 2. The input/output circuit 12 transfers a control signal CNT and a command CMD received from the memory controller 2 to the control circuit 13. The input/output circuit 12 transfers a row address and a column address included in an address signal ADD received from the memory controller 2 to the row selection circuit 14 and the column selection circuit 15, respectively. The input/output circuit 12 transfers data DAT (write data) received from the memory controller 2 to the write circuit 16. The input/output circuit 12 transfers data DAT (read data) received from the read circuit 17 to the memory controller 2.

The control circuit 13 controls the operation of the entire magnetic memory device 1. For example, the control circuit 13 executes a read operation, a write operation, etc. based on control instructed by the control signal CNT and the command CMD. For example, the control circuit 13 supplies the write circuit 16 with a voltage for use in data writing in the write operation. In addition, the control circuit 13 supplies the read circuit 17 with a voltage for use in data reading in the read operation.

The row selection circuit 14 is coupled to a plurality of word lines WL. Then, the row selection circuit 14 selects a word line WL specified by a row address. The selected word line WL is, for example, electrically coupled to a driver circuit, illustration of which is omitted.

The column selection circuit 15 is coupled to a plurality of bit lines BL. Then, the column selection circuit 15 selects one or more bit lines BL specified by a column address. The selected bit line BL is, for example, electrically coupled to a driver circuit, illustration of which is omitted.

The write circuit 16 supplies the column selection circuit 15 with a voltage for use in data writing based on the control of the control circuit 13 and the data DAT (write data) received from the input/output circuit 12. When a current based on the write data passes through a memory cell MC, desired data is written to the memory cell MC.

The read circuit 17 includes a sense amplifier. The read circuit 17 supplies the column selection circuit 15 with a voltage for use in data reading based on the control of the control circuit 13. Then, the sense amplifier determines data stored in the memory cell MC based on a voltage or a current of the selected bit line BL. Then, the read circuit 17 transfers data DAT (read data) corresponding to a determination result to the input/output circuit 12.

### [1-2] Circuit Configuration of Memory Cell Array 11

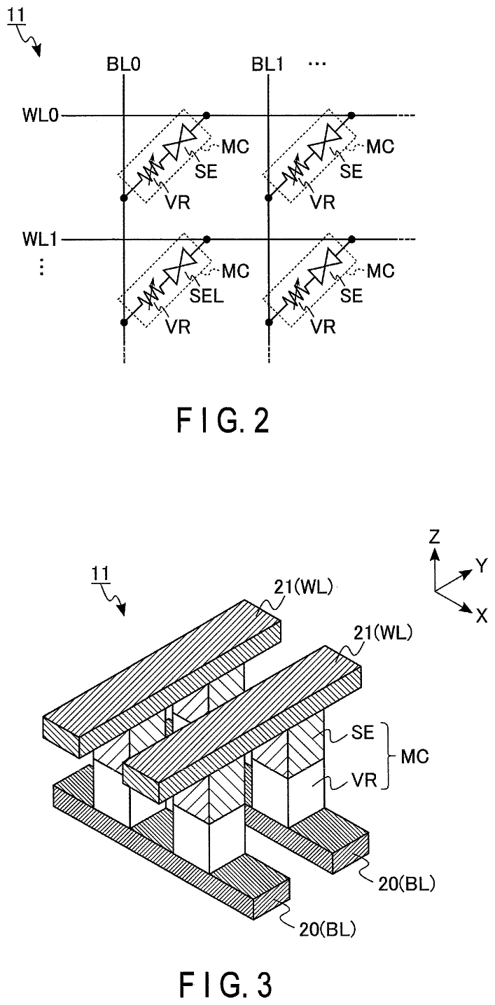

FIG. 2 is a circuit diagram showing an example of a circuit configuration of the memory cell array 11 included in the magnetic memory device 1 according to the embodiment. FIG. 2 extracts and shows WL0 and WL1 among a plurality of word lines WL and BL0 and BL1 among a plurality of bit lines BL. As shown in FIG. 2, one memory cell MC each is coupled between WL0 and BL0, WL0 and BL1, WL1 and BL0, and WL1 and BL1. In the memory cell array 11, a plurality of memory cells MC are arranged in a matrix, for example.

Each memory cell MC includes a variable resistance element VR and a switching element SE. The variable resistance element VR and the switching element SE are coupled in series between the associated bit line BL and word line WL. For example, one end of the variable resistance element VR is coupled to the bit line BL. The other end of the variable resistance element VR is coupled to one end of the switching element SE. The other end of the switching element SE is coupled to the word line WL. A coupling relationship between the variable resistance element VR and the switching element SE between the bit line BL and the word line WL may be reversed.

The variable resistance element VR corresponds to an MTJ element. The variable resistance element VR may store data in a nonvolatile manner based on the resistance value thereof. For example, a memory cell MC including a variable resistance element VR in a high-resistance state stores “1” data. A memory cell MC including a variable resistance element VR in a low-resistance state stores “0” data. Allocation of the data associated with the resistance value of the variable resistance element VR may be set differently. The resistance state of the variable resistance element VR may vary depending on the current passing through the variable resistance element VR.

The switching element SE is, for example, a bidirectional diode. The switching element SE functions as a selector which controls supply of a current to the associated variable resistance element VR. Specifically, the switching element SE included in a memory cell MC is turned off when the voltage applied to that memory cell MC is below a threshold voltage of the switching element SE, and is turned on when the voltage applied to the memory cell MC is equal to or greater than the threshold voltage of the switching element SE. In an OFF state, the switching element SE functions as an insulator having a high resistance value. When the switching element SE is in an OFF state, a current flow between the word line WL and the bit line BL coupled to that memory cell MC is suppressed. In an ON state, the switching element SE functions as a conductor having a low resistance value. When the switching element SE is in an ON state, a current flows between the word line WL and the bit line BL coupled to that memory cell MC. Namely, the switching element SE is capable of switching between whether or not to pass a current according to the magnitude of the voltage applied to the memory cell MC, regardless of the direction of the current flow. As the switching element SE, other elements such as a transistor may be used.

### [1-3] Structure of Memory Cell Array 11

An example of a structure of the memory cell array 11 according to the embodiment will be described below. In the following descriptions, an xyz orthogonal coordinate system will be used. An X direction corresponds to a direction in which the bit line BL extends. A Y direction corresponds to a direction in which the word line WL extends. A Z direction corresponds to a direction vertical to the surface of the semiconductor substrate used for forming the magnetic memory device 1. The term “low” and its derivatives and relevant terms refer to a position with a smaller coordinate on the z axis. The term “up” and its derivatives and relevant terms refer to a position with a larger coordinate on the z axis. In the perspective views, hatching is applied, where necessary. The hatching applied in the perspective views does not necessarily relate to the material or characteristics of the hatched components. In the perspective views and the cross-sectional views, illustration of the components such as an interlayer insulating film is omitted.

### [1-3-1] Two-Dimensional Structure of Memory Cell Array 11

FIG. 3 is a perspective view showing an example of a structure of the memory cell array 11 included in the magnetic memory device 1 according to the embodiment. As shown in FIG. 3, the memory cell array 11 includes a plurality of conductive layers 20 and a plurality of conductive layers 21.

Each of the conductive layers 20 has a portion extending in the X direction. The conductive layers 20 are arranged in the Y direction and spaced apart from each other. Each conductive layer 20 is used as a bit line BL.

Each of the conductive layers 21 has a portion extending in the Y direction. The conductive layers 21 are arranged in the X direction and spaced apart from each other. Each conductive layer 21 is used as a word line WL.

An interconnect layer provided with the conductive layers 21 is provided above an interconnect layer provided with the conductive layers 20. One memory cell MC is provided at each of portions where the conductive layers 20 and the conductive layers 21 cross each other. In other words, each memory cell MC is provided in a columnar shape between the associated bit line BL and word line WL. In this example, the variable resistance element VR is provided on the conductive layer 20. The switching element SE is provided on the variable resistance element VR. The conductive layer 21 is provided on the switching element SE.

Although a case has been described in which the variable resistance element VR is provided below the switching element SE, the variable resistance element VR may be provided above the switching element SE depending on the circuit configuration of the memory cell array 11.

### [1-3-2] Cross-Sectional Structure of Variable Resistance Element VR

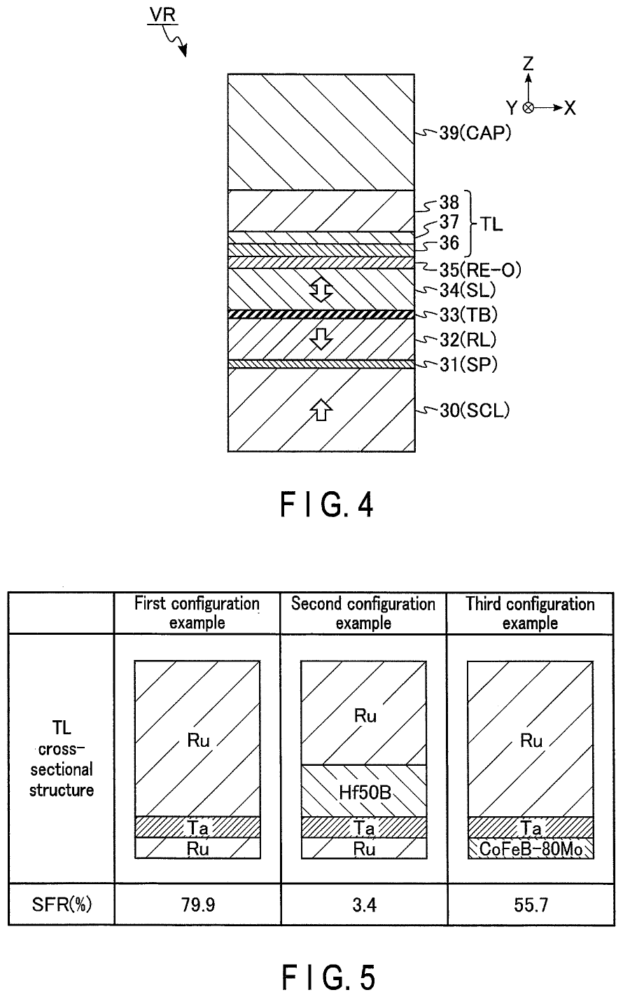

FIG. 4 is a cross-sectional diagram showing an example of a cross-sectional structure of the variable resistance element VR included in the memory cell MC of the magnetic memory device 1 according to the embodiment. As shown in FIG. 4, the variable resistance element VR includes, for example, a ferromagnetic layer 30, a nonmagnetic layer 31, a ferromagnetic layer 32, a nonmagnetic layer 33, a ferromagnetic layer 34, and nonmagnetic layers 35 to 39. In FIG. 4, a magnetization direction of a magnetic layer is indicated by an arrow. A bidirectional arrow indicates that the magnetization direction is variable.

The ferromagnetic layer 30, nonmagnetic layer 31, ferromagnetic layer 32, nonmagnetic layer 33, ferromagnetic layer 34, and nonmagnetic layers 35 to 39 are stacked in this order from the conductive layer 20 (bit line BL) side toward the conductive layer 21 (word line WL) side. Specifically, the ferromagnetic layer 30 is provided above the conductive layer 20. The nonmagnetic layer 31 is provided on the ferromagnetic layer 30. The ferromagnetic layer 32 is provided on the nonmagnetic layer 31. The nonmagnetic layer 33 is provided on the ferromagnetic layer 32. The ferromagnetic layer 34 is provided on the nonmagnetic layer 33. The nonmagnetic layer 35 is provided on the ferromagnetic layer 34. The nonmagnetic layer 36 is provided on the nonmagnetic layer 35. The nonmagnetic layer 37 is provided on the nonmagnetic layer 36. The nonmagnetic layer 38 is provided on the nonmagnetic layer 37. The nonmagnetic layer 39 is provided on the nonmagnetic layer 38. The conductive layer 21 is provided above the nonmagnetic layer 39.

The ferromagnetic layer 30 is a ferromagnetic conductor. The ferromagnetic layer 30 has an axis of easy magnetization in a direction perpendicular to the film surface. In the example shown in FIG. 4, the magnetization direction of the ferromagnetic layer 30 is oriented toward the ferromagnetic layer 32 side. The magnetic field intensity necessary for reversing the magnetization direction of the ferromagnetic layer 30 is, for example, larger than the magnetic field intensity necessary for reversing the magnetization direction of the ferromagnetic layer 32. A stray field from the ferromagnetic layer 30 reduces an influence of a stray field from the ferromagnetic layer 32 on a magnetization direction of the ferromagnetic layer 34. That is, the ferromagnetic layer 30 functions as a shift canceling layer SCL. The ferromagnetic layer 30 contains, for example, at least one element selected from the group consisting of iron (Fe), cobalt (Co), and nickel (Ni). The ferromagnetic layer 30 may further contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 30 may contain cobalt iron boron (CoFeB). The ferromagnetic layer 30 may contain at least one binary compound selected from the group consisting of iron boride (FeB), cobalt platinum (CoPt), cobalt nickel (CoNi), and cobalt palladium (Coed).

The nonmagnetic layer 31 is a nonmagnetic conductor. The nonmagnetic layer 31 is used as a spacer layer SP, and is antiferromagnetically coupled to the ferromagnetic layer 30. Thus, the magnetization direction of the ferromagnetic layer 30 is fixed to a direction antiparallel to the magnetization direction of the ferromagnetic layer 32. Such a coupling structure of the ferromagnetic layer 30, nonmagnetic layer 31, and ferromagnetic layer 32 is referred to as a synthetic anti-ferromagnetic (SAF) structure. The nonmagnetic layer 31 contains, for example, at least one element selected from the group consisting of ruthenium (Ru), osmium (Os), iridium (Ir), vanadium (V), and chromium (Cr).

The ferromagnetic layer 32 is a ferromagnetic conductor. The ferromagnetic layer 32 has an axis of easy magnetization in a direction perpendicular to the film surface. The magnetization direction of the ferromagnetic layer 32 is fixed to the ferromagnetic layer 30 side or the ferromagnetic layer 34 side. In the example shown in FIG. 4, the magnetization direction of the ferromagnetic layer 32 is fixed to the ferromagnetic layer 30 side. Thus, the ferromagnetic layer 32 is used as a reference layer RL of the MTJ element. The reference layer RL may be referred to as a “pin layer” or a “fixed layer”. The ferromagnetic layer 32 contains, for example, at least one element selected from the group consisting of iron (Fe), cobalt (Co), and nickel (Ni). The ferromagnetic layer 32 may further contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 32 may contain cobalt iron boron (CoFeB). The ferromagnetic layer 32 may contain at least one binary compound selected from the group consisting of iron boride (FeB), cobalt platinum (CoPt), cobalt nickel (CoNi), and cobalt palladium (Coed).

The nonmagnetic layer 33 is a nonmagnetic insulator. The ferromagnetic layer 33 forms a magnetic tunnel junction together with the ferromagnetic layers 32 and 34. That is, the nonmagnetic layer 33 functions as a tunnel barrier layer of the MTJ element. Further, the nonmagnetic layer 33 functions as a seed material during a crystallization process of the ferromagnetic layers 32 and 34 included in a manufacturing process of the magnetic memory device 1. This seed material corresponds to a material to be a nucleus for growth of a crystalline film from an interface with the ferromagnetic layers 32 and 34. The nonmagnetic layer 33 contains, for example, an oxide of at least one element or compound selected from the group consisting of magnesium (Mg), aluminum (Al), zinc (Zn), titanium (Ti), and lanthanum-strontium-manganese (LSM).

The ferromagnetic layer 34 is a ferromagnetic conductor. The ferromagnetic layer 34 has an axis of easy magnetization in a direction perpendicular to the film surface. The magnetization direction of the ferromagnetic layer 34 is a direction toward either the ferromagnetic layer 32 side or the nonmagnetic layer 35 side. The magnetization direction of the ferromagnetic layer 34 is formed to be reversed more easily than that of the ferromagnetic layer 32. Thus, the ferromagnetic layer 34 is used as a storage layer SL of the MTJ element. The storage layer SL may be referred to as a “free layer”. The ferromagnetic layer 34 contains, for example, at least one element selected from the group consisting of iron (Fe), cobalt (Co), and nickel (Ni). The ferromagnetic layer 34 may further contain, as impurities, at least one element selected from the group consisting of boron (B), phosphorus (P), carbon (C), aluminum (Al), silicon (Si), tantalum (Ta), molybdenum (Mo), chromium (Cr), hafnium (Hf), tungsten (W), and titanium (Ti). Specifically, the ferromagnetic layer 34 may contain cobalt iron boron (CoFeB) or an iron boride (FeB).

The nonmagnetic layer 35 is an oxide of a rare-earth element. An oxide of a rare-earth element is also referred to as a “rare-earth oxide (RE-O)”. The nonmagnetic layer 35 is used as a capping layer with respect to the ferromagnetic layer 34 (storage layer SL). The rare-earth element contained in the nonmagnetic layer 35 has a crystalline structure of which grid spacing of a bond (for example, a covalent bond) is larger than grid spacings of bonds of the other elements. Therefore, if a layer adjacent to the nonmagnetic layer 35 is non-crystalline (in an amorphous state) and contains impurities, the nonmagnetic layer 35 has a function of diffusing those impurities into the nonmagnetic layer 35 in a high-temperature environment (for example, during an annealing treatment). Specifically, the nonmagnetic layer 35 has a function of removing impurities from the amorphous ferromagnetic layer 34 to bring the ferromagnetic layer 34 to a highly oriented crystallized state through the annealing treatment. The nonmagnetic layer 35 contains, for example, an oxide of at least one element selected from the group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

The nonmagnetic layer 36 is a nonmagnetic conductor. The nonmagnetic layer 36 contains iron (Fe), cobalt (Co), and boron (B). Further, the nonmagnetic layer 36 may contain cobalt iron boron (CoFeB), which is a ternary compound. Specifically, the nonmagnetic layer 36 has a configuration to which a nonmagnetic element is added to CoFeB, which is originally a ferromagnet, until CoFeB loses ferromagnetism and exhibits nonmagnetism. For example, in the nonmagnetic layer 36, an addition amount of the nonmagnetic element to make nonmagnetic CoFeB is 40 at % or more. The nonmagnetic layer 36 contains at least one element selected from the group consisting of molybdenum (Mo) and tungsten (W) as nonmagnetic element impurities. That is, the nonmagnetic layer 36 may contain cobalt iron boron containing molybdenum as impurities (CoFeB—Mo). Alternatively, the nonmagnetic layer 36 may contain cobalt iron boron containing tungsten as impurities (CoFeB—W). In a case where the nonmagnetic layer 36 contains CoFeB—Mo, a content ratio of molybdenum (Mo) in the nonmagnetic layer 36 is preferably designed to be 50 at % or more and 80 at % or less.

The nonmagnetic layer 37 is a nonmagnetic conductor. The nonmagnetic layer 37 contains, for example, at least one element selected from the group consisting of scandium (Sc), titanium (Ti), yttrium (Y), zirconium (Zr), niobium (Nb), molybdenum (Mo), ruthenium (Ru), hafnium (Hf), tantalum (Ta), and tungsten (W). Further, the nonmagnetic layer 37 may contain an alloy containing two or more elements selected from the group consisting of scandium (Sc), titanium (Ti), yttrium (Y), zirconium (Zr), niobium (Nb), molybdenum (Mo), ruthenium (Ru), hafnium (Hf), tantalum (Ta), and tungsten (W). In addition, the nonmagnetic layer 37 may contain a nitride or boride of one element selected from the group consisting of scandium Sc), titanium (Ti), yttrium (Y), zirconium (Zr), niobium (Nb), molybdenum (Mo), ruthenium (Ru), hafnium (Hf), tantalum (Ta), and tungsten (W).

The nonmagnetic layer 38 is a nonmagnetic conductor. The nonmagnetic layer 38 contains, for example, at least one element selected from the group consisting of platinum (Pt), tungsten (W), tantalum (Ta), and ruthenium (Ru). A set of nonmagnetic layers 36, 37, and 38 is used as a top layer TL. The top layer TL may have, for example, a function of enhancing the characteristics of the MTJ element, a function as a hard mask, and a function as an electrode.

The nonmagnetic layer 39 is a nonmagnetic conductor. The nonmagnetic layer 39 is used as a capping layer CAP with respect to the top layer TL. The capping layer CAP may be used as an electrode that enhances electrical connectivity between the variable resistance element VR and an upper element (e.g., a switching element SE) or an interconnect (e.g., a bit line BL). The nonmagnetic layer 39 contains, for example, at least one element selected from platinum (Pt), tungsten (W), tantalum (Ta), and ruthenium (Ru).

The variable resistance element VR described above functions as a perpendicular magnetization-type MTJ element that utilizes the tunneling magnetoresistance (TMR) effect. The variable resistance element VR may be in either a low-resistance state or a high-resistance state according to the relative relationship between the magnetization directions of the ferromagnetic layers 32 and 34. Specifically, the variable resistance element VR is in a high-resistance state when the magnetization directions of the reference layer RL and the storage layer SL are in an antiparallel state (AP-state), and is in a low-resistance state when the magnetization directions of the reference layer RL and the storage layer SL are in a parallel state (P-state).

The magnetic memory device 1 can store desired data in the memory cell MC by changing the magnetization direction of the ferromagnetic layer 34 (storage layer SL). Specifically, the magnetic memory device 1 controls the magnetization direction of the storage layer SL by passing a write current to the variable resistance element VR to inject spin torque into the storage layer SL and the reference layer RL. Such a write method is called a “spin-injection write method”.

In this example, the variable resistance element VR enters the AP-state when a write current is passed in a direction from the ferromagnetic layer 32 toward the ferromagnetic layer 34, and enters the P-state when a write current is passed in a direction from the ferromagnetic layer 34 toward the ferromagnetic layer 32. The variable resistance element VR is configured so that the magnetization direction of the ferromagnetic layer 32 remains unchanged when a current having a magnitude that may cause the magnetization direction of the ferromagnetic layer 34 to be reversed is passed to the variable resistance element VR. That is, the expression “a magnetization direction is fixed” means that the magnetization direction does not change in response to an electric current of such a magnitude that the magnetization direction of the ferromagnetic layer 34 may be reversed.

In the variable resistance element VR, only the nonmagnetic layer 35 is provided between the ferromagnetic layer 34 and the nonmagnetic layer 36. That is, a capping structure formed between the ferromagnetic layer 34 and the nonmagnetic layer 36 is formed by one nonmagnetic layer 35, which is an oxide of a rare-earth element. The variable resistance element VR may also include other layers, and each magnetic layer, except for the nonmagnetic layer 35, may be formed by a plurality of layers. For example, the ferromagnetic layer 32 may be a layer stack including a plurality of layers. A layer stack that constitutes the ferromagnetic layer 32 may have, for example, a layer containing cobalt iron boron (CoFeB) or iron boron (FeB) as an interface layer with the nonmagnetic layer 33 while having an additional ferromagnetic layer between that interface layer and the nonmagnetic layer 31 with a nonmagnetic conductor interposed therebetween.

### [2] SFR and MTJ Characteristics in Variable Resistance Element VR

In the following, an SFR (shunt fail rate) and MTJ characteristics in the variable resistance element VR will be described. The SFR indicates a rate of occurrence of a failure (shunt failure) due to a short-circuit of a storage layer SL and a reference layer RL in an MTJ element (variable resistance element VR). The MTJ characteristics are at least one index related to the characteristics of the MTJ element. In the present specification, a description will be given using a thermal stability index Δ and a magnetoresistance (MR) ratio as the MTJ characteristics.

Δ indicates the thermal stability of bit information that the MTJ element stores, and is expressed by the formula “Δ=E_{b}/k_{B}T”, for example. In the present formula, “E_{b}” is an energy barrier required for magnetization reversal. “k_{B}” is a Boltzmann constant. “T” is an absolute temperature. It is preferable that the value of Δ in the MTJ element (variable resistance element VR) be large.

The MR ratio indicates a difference between an electric resistance when the magnetic tunnel junction is in an antiparallel state (AP-state) and an electric resistance when the magnetic tunnel junction is in a parallel state (P-state). The MR ratio is indicated by, for example, a ratio between a high-resistance state and a low-resistance state (resistance value in a high-resistance state/resistance value in a low-resistance state). It is preferable that the value of the MR ratio in the MTJ element (variable resistance element VR) be large.

Note that numerical values of the SFR, Δ, and MR ratio to be used in the descriptions below are only examples. The respective values of the SFR, Δ, and MR ratio shown in the same figure correspond to results of evaluating the configurations of the variable resistance element VR shown in that figure under the same conditions.

### [2-1] Change in Characteristics Based on Difference in Stacked Structure of Top Layer TL

FIG. 5 is a schematic diagram showing an example of a change in characteristics based on a difference in stacked structure of a top layer TL. FIG. 5 shows a TL cross-sectional structure (a cross-sectional structure of the top layer TL) of the top layer TL and an SFR (%) in each of a first configuration example, a second configuration example, and a third configuration example. In the cross-sectional structures shown in FIG. 5, the lower side of the paper surface corresponds to the nonmagnetic layer 35 side, and the upper side of the paper surface corresponds to the nonmagnetic layer 39 side. In the following, a change in characteristics based on a difference in stacked structure of the top layer TL will be described with reference to FIG. 5.

The top layer TL in the first configuration example has a structure in which ruthenium (Ru), tantalum (Ta), and ruthenium (Ru) are stacked in this order. That is, the top layer TL in the first configuration example has a structure in which Ru is provided at the position of the nonmagnetic layer 36, Ta is provided at the position of the nonmagnetic layer 37, and Ru is provided at the position of the nonmagnetic layer 38 with respect to the stacked structure of the top layer TL in the embodiment. In the top layer TL in the first configuration example, SFR=79.9.

The top layer TL in the second configuration example has a structure in which ruthenium (Ru), tantalum (Ta), hafnium boride (Hf50B), and ruthenium (Ru) are stacked in this order. That is, the top layer TL in the second configuration example has a structure in which a portion of Ru on the upper layer side that is adjacent to Ta is replaced with Hf50B with respect to the stacked structure of the top layer TL in the first configuration example. Hf50B is a hafnium boride to which boron (B) is added at 50 at %. In the top layer TL in the second configuration example, SFR=3.4. That is, as a result of providing Hf50B on the nonmagnetic layer 37 in the top layer TL in the second configuration example, the SFR is improved as compared to that of the first configuration example.

The top layer TL in the third configuration example has a structure in which cobalt iron boron (CoFeB-80Mo) containing molybdenum (Mo) as impurities, tantalum (Ta), and ruthenium (Ru) are stacked in this order. That is, the top layer TL in the third configuration example has a structure in which Ru is replaced with CoFeB-80Mo with respect to the stacked structure of the top layer TL in the first configuration example. CoFeB-80Mo is cobalt iron boron to which molybdenum (Mo) is added at 80 at %. In the top layer TL in the third configuration example, SFR=55.7. That is, as a result of providing CoFeB-80Mo between the nonmagnetic layers 35 and 37 in the top layer TL in the third configuration example, the SFR is improved as compared to that of the first configuration example.

### [2-2] Change in Characteristics Based on Difference in Material of Top Layer TL

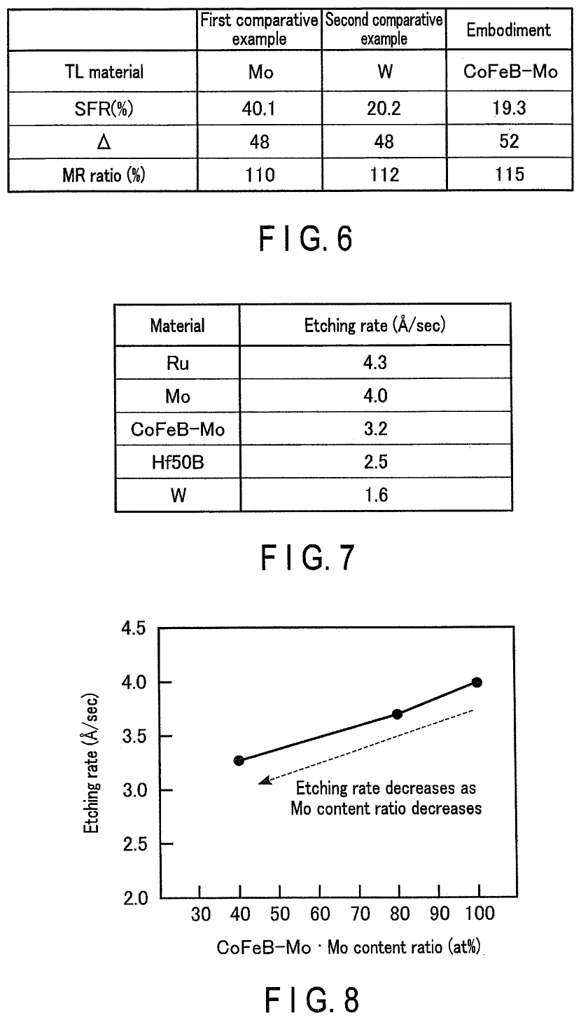

FIG. 6 is a table showing an example of a change in characteristics based on a difference in material of the top layer TL. FIG. 6 shows a TL material, an SFR (%), Δ, and an MR ratio (%) of the top layer TL in each of a first comparative example, a second comparative example, and an embodiment. Note that the TL material in FIG. 6 indicates a material of a layer corresponding to the nonmagnetic layer 36 among the stacked structure of the top layer TL of the embodiment described using FIG. 4. In this example, the nonmagnetic layer 37 is a hafnium boride to which boron (B) is added at 50 at % (Hf50B), and the nonmagnetic layer 38 is ruthenium (Ru). In the following, a change in characteristics based on a difference in material of the nonmagnetic layer 36 will be described with reference to FIG. 6.

The top layer TL in the first comparative example contains molybdenum (Mo) as the TL material. That is, the top layer TL in the first comparative example has a structure in which a molybdenum layer is provided on the nonmagnetic layer 35 and the nonmagnetic layers 37 and 38 are stacked on that molybdenum layer. In the top layer TL in the first comparative example, SFR=40.1, Δ=48, and MR ratio=110.

The top layer TL in the second comparative example contains tungsten (W) as the TL material. That is, the top layer TL in the second comparative example has a structure in which a tungsten layer is provided on the nonmagnetic layer 35 and the nonmagnetic layers 37 and 38 are stacked on that tungsten layer. In the top layer TL in the second comparative example, SFR=20.2, Δ=48, and MR ratio=112.

The top layer TL in the embodiment contains CoFeB—Mo (cobalt iron boron with molybdenum added as impurities) as the TL material. In the top layer TL in the embodiment, SFR=19.3, Δ=52, and MR ratio=115. That is, in the top layer TL in the embodiment, each of the SFR, Δ, and MR ratio is more favorable than that in each of the first comparative example and the second comparative example. Such a change in characteristics of the variable resistance element VR is presumed to depend on, for example, an etching rate (i.e., the hardness of the top layer TL) of the material used for the top layer TL.

(Etching Rate of Material used for Top Layer TL)

FIG. 7 is a table showing examples of etching rates of materials used for the top layer TL. FIG. 7 indicates the etching rate when the material formed in a single film on the substrate is etched by IBE (ion beam etching) under a predetermined condition. As shown in FIG. 7, the etching rate of Ru is 4.3 (Å/sec), the etching rate of Mo is 4.0 (Å/sec), the etching rate of CoFeB—Mo is 3.2 (Å/sec), the etching rate of Hf50B is 2.5 (Å/sec), and the etching rate of W is 1.6 (Å/sec).

That is, in this example, a processing speed in the IBE is Ru>Mo>CoFeB—Mo>Hf50B>W. If the IBE conditions are identical, the material with the lower etching rate can be considered the harder layer. In this example, the addition of molybdenum (Mo) to cobalt iron boron (CoFeB) results in a lower etching rate than a layer composed only of Mo. Similarly, cobalt iron boron with tungsten added (CoFeB—W) can exhibit a lower etching rate than that for the CoFeB—Mo layer; W has a lower etching rate than a single Mo.

### (Relationship Between Mo Content Ratio and Etching Rate of Nonmagnetic Layer 36)

FIG. 8 is a graph showing an example of a relationship between a content ratio of molybdenum (Mo content ratio) contained in a layer (e.g., the nonmagnetic layer 36) of cobalt iron boron (CoFeB) of the top layer TL and an etching rate. In the graph shown in FIG. 8, an abscissa axis indicates the Mo content ratio of CoFeB—Mo, and an ordinate axis indicates an etching rate (A/sec) of CoFeB—Mo under a predetermined IBE condition. As shown in FIG. 8, the etching rate of CoFeB—Mo tends to decrease as the Mo content ratio in CoFeB—Mo is reduced. In other words, under the same IBE condition, the hardness of CoFeB tends to increase as the Mo addition amount decreases.

[2-3] Change in Anisotropic Magnetic Field of Storage Layer SL based on Mo Content Ratio of Nonmagnetic Layer 36

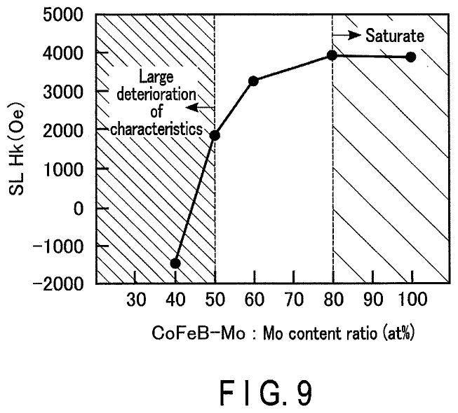

FIG. 9 is a graph showing an example of a relationship between a content ratio of molybdenum (Mo) contained in a layer (e.g., the nonmagnetic layer 36) of cobalt iron boron of the top layer TL and an anisotropic magnetic field of the storage layer SL. In the graph shown in FIG. 9, an abscissa axis indicates the Mo content ratio of CoFeB—Mo, and an ordinate axis indicates an anisotropic magnetic field (Oe) of the storage layer SL. Hereinafter, the anisotropic magnetic field of the storage layer SL will be referred to as “SL_Hk”. Note that “SL_Hk” may be referred to as a perpendicular magnetic anisotropic magnetic field of the storage layer SL.

As shown in FIG. 9, SL_Hk changes according to the Mo content ratio of CoFeB (the nonmagnetic layer 36). Specifically, SL_Hk largely decreases when the Mo content ratio is less than 50 at %. On the other hand, SL Hk is an approximately constant value when the Mo content ratio exceeds 80 at %. In other words, in the embodiment, the MTJ characteristics of the variable resistance element VR are significantly deteriorated when the Mo content ratio of CoFeB—Mo is less than 50 at %, become favorable as the Mo content ratio increases, and saturate when the Mo content ratio exceeds 80 at %.

### [3] Advantageous Effects of Embodiment

With the magnetic memory device 1 according to the embodiment described above, it is possible to maintain the characteristics of the memory cells MC and suppress the occurrence of a failure. Details of the advantageous effect of the magnetic memory device 1 according to the embodiment will be described below.

As a method of increasing the storage capacity of the magnetic memory device, arranging the memory cells MC in a high density is conceivable. However, when the memory cells MC are arranged in a high density, the SFR may increase because the memory cells MC are arranged in a narrow pitch. Since there is a trade-off between measures to reduce the SFR and the MTJ characteristics, it is preferable to improve the SFR while maintaining the MTJ characteristics as much as possible.

The shunt failure in the MTJ elements is presumed to be a failure caused by influences during the processing of the memory cells MC. That is, reducing damage to the memory cells MC when they are processed is considered effective in reducing the shunt failure. For example, it may be possible to improve (reduce) the SFR by reducing the etching rate of the top layer TL, i.e., by using a harder material for the top layer TL.

In addition, as a structure of the MTJ element, a structure in which a rare-earth oxide RE-O is provided on the storage layer SL in order to enhance the magnetic characteristics of the MTJ element is known. In such a structure, a stacked structure of the top layer TL provided on the rare-earth oxide RE-O may affect both the SFR and the MTJ characteristics. As the stacked structure of the top layer TL, for example, a stacked structure (Ru/HfB) in which ruthenium (Ru) is provided on a hafnium boride (HfB) is known. The stacked structure of Ru/HfB is a material emphasizing processing characteristics of the memory cell MC. However, when HfB is provided directly above the rare-earth oxide RE-O, the MTJ characteristics (e.g., the magnetic characteristics of the storage layer SL) tend to deteriorate.

Accordingly, the MTJ element (variable resistance element VR) of the magnetic memory device 1 according to the embodiment has a configuration in which a layer (the nonmagnetic layer 36) for achieving both the processing characteristics and MTJ characteristics is provided between HfB (the nonmagnetic layer 37) and the rare-earth oxide RE-O (the nonmagnetic layer 35). Then, in the variable resistance element VR of the embodiment, CoFeB—Mo (cobalt iron boron with molybdenum added) or CoFeB—W (cobalt iron boron with tungsten added) is used as the nonmagnetic layer 36.

CoFeB—Mo and CoFeB—W are each harder than when the nonmagnetic layer 36 consists of a single layer of molybdenum. As a result, the stacked structure of the variable resistance element VR can suppress the occurrence of a shunt failure and improve the SFR. Further, each of CoFeB—Mo and CoFeB—W provided on the rare-earth oxide RE-O can enhance the MTJ characteristics. That is, the stacked structure of the variable resistance element VR can suppress deterioration of the MTJ characteristics. Accordingly, the magnetic memory device 1 according to the embodiment can maintain the characteristics of the memory cells MC and suppress the occurrence of a failure.

As for CoFeB—Mo, as described with reference to FIGS. 8 and 9, the etching rate may change and the magnetic characteristics (SL_Hk) of the storage layer SL may change according to the content ratio of impurities added. That is, the addition amount of molybdenum should be adjusted so as to achieve both the MTJ characteristics and the SFR reduction. Specifically, in a case where the top layer TL is formed by a stacked structure of CoFeB—Mo, HfB, and Ru, the content ratio of molybdenum that makes the nonmagnetic layer 36 harder than a single layer of Mo while SL_Hk is maintained is preferably 50 at % or more and 80 at % or less.

### [4] Others

In the embodiment, the magnetic memory device 1 has been described as an example of a magnetic device including an MTJ element (variable resistance element VR), but the embodiment is not limited thereto. The magnetic device may be other devices that require a magnetic element having perpendicular magnetic anisotropy such as a sensor or a medium. It suffices that that magnetic element uses at least a variable resistance element VR.

In the present specification, the term “couple” refers to electrical coupling, and does not exclude interposition of another component. Each of the nonmagnetic layers 31 and 36 to 39 may be referred to as a “conductive layer”. Each of the nonmagnetic layers 33 and 35 may be referred to as an “oxide layer”. In the present specification, the expression “content ratio” refers to an atomic percentage (at %). The content ratio can be measured by, for example, using electron energy loss spectroscopy (EELS) with a scanning transmission electron microscope (STEM).

While certain embodiments have been described, these embodiments have been presented by way of example only, and are not intended to limit the scope of the inventions. Indeed, the novel embodiments described herein may be embodied in a variety of other forms; furthermore, various omissions, substitutions and changes in the form of the embodiments described herein may be made without departing from the spirit of the inventions. The accompanying claims and their equivalents are intended to cover such forms or modifications as would fall within the scope and spirit of the inventions.

1. A magnetic memory device comprising:
a first ferromagnetic layer;
a first nonmagnetic layer on the first ferromagnetic layer;
a second ferromagnetic layer on the first nonmagnetic layer;
an oxide layer on the second ferromagnetic layer; and
a second nonmagnetic layer on the oxide layer, wherein
the oxide layer contains an oxide of a rare-earth element, and
the second nonmagnetic layer contains cobalt (Co), iron (Fe), boron (B), and molybdenum (Mo).

2. The device of claim 1, wherein
the second nonmagnetic layer contains molybdenum (Mo) and cobalt iron boron (CoFeB).

3. The device of claim 1, wherein
a content ratio of molybdenum (Mo) in the second nonmagnetic layer is 50 at % or more and 80 at % or less.

4. The device of claim 1, wherein
the oxide layer contains an oxide of at least one element selected from a group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

5. The device of claim 1, further comprising:
a third nonmagnetic layer on the second nonmagnetic layer; and
a fourth nonmagnetic layer on the third nonmagnetic layer, wherein
the third nonmagnetic layer contains at least one element selected from a group consisting of scandium (Sc), titanium (Ti), yttrium (Y), zirconium (Zr), niobium (Nb), molybdenum (Mo), ruthenium (Ru), hafnium (Hf), tantalum (Ta), and tungsten (W), and
the fourth nonmagnetic layer contains at least one element selected from a group consisting of platinum (Pt), tungsten (W), tantalum (Ta), and ruthenium (Ru).

6. A magnetic memory device comprising:
a first ferromagnetic layer;
a first nonmagnetic layer on the first ferromagnetic layer;
a second ferromagnetic layer on the first nonmagnetic layer;
an oxide layer on the second ferromagnetic layer; and
a second nonmagnetic layer on the oxide layer, wherein
the oxide layer contains an oxide of gadolinium (Gd), and
the second nonmagnetic layer contains cobalt (Co), iron (Fe), boron (B), and molybdenum (Mo).

7. The device of claim 6, wherein
the second nonmagnetic layer is a layer containing molybdenum (Mo) and cobalt iron boron (CoFeB).

8. The device of claim 6, wherein
a content ratio of molybdenum (Mo) in the second nonmagnetic layer is 50 at % or more and 80 at % or less.

9. The device of claim 6, further comprising:
a third nonmagnetic layer on the second nonmagnetic layer; and
a fourth nonmagnetic layer on the third nonmagnetic layer, wherein
the third nonmagnetic layer contains a boride of hafnium (Hf), and
the fourth nonmagnetic layer contains at least one element selected from a group consisting of platinum (Pt), tungsten (W), tantalum (Ta), and ruthenium (Ru).

10. The device of claim 9, wherein
the fourth nonmagnetic layer contains ruthenium (Ru).

11. A magnetic memory device comprising:
a first ferromagnetic layer;
a first nonmagnetic layer on the first ferromagnetic layer;
a second ferromagnetic layer on the first nonmagnetic layer;
an oxide layer on the second ferromagnetic layer; and
a second nonmagnetic layer on the oxide layer, wherein
the oxide layer contains an oxide of a rare-earth element, and
the second nonmagnetic layer contains cobalt (Co), iron (Fe), boron (B), and tungsten (W).

12. The device of claim 11, wherein
the second nonmagnetic layer contains tungsten (W) and cobalt iron boron (CoFeB).

13. The device of claim 11, wherein
the oxide layer contains an oxide of at least one element selected from a group consisting of scandium (Sc), yttrium (Y), lanthanum (La), cerium (Ce), praseodymium (Pr), neodymium (Nd), promethium (Pm), samarium (Sm), europium (Eu), gadolinium (Gd), terbium (Tb), dysprosium (Dy), holmium (Ho), erbium (Er), thulium (Tm), ytterbium (Yb), and lutetium (Lu).

14. The device of claim 11, further comprising:
a third nonmagnetic layer on the second nonmagnetic layer; and
a fourth nonmagnetic layer on the third nonmagnetic layer, wherein
the third nonmagnetic layer contains at least one element selected from a group consisting of scandium (Sc), titanium (Ti), yttrium (Y), zirconium (Zr), niobium (Nb), molybdenum (Mo), ruthenium (Ru), hafnium (Hf), tantalum (Ta), and tungsten (W), and
the fourth nonmagnetic layer contains at least one element selected from a group consisting of platinum (Pt), tungsten (W), tantalum (Ta), and ruthenium (Ru).

15. The device of claim 1, further comprising:
a third ferromagnetic layer under the first ferromagnetic layer; and
a fifth nonmagnetic layer between the third ferromagnetic layer and the first ferromagnetic layer, wherein
the fifth nonmagnetic layer contains at least one element selected from a group consisting of ruthenium (Ru), osmium (Os), iridium (Ir), vanadium (V), and chromium (Cr).

16. The device of claim 15, wherein
the fifth nonmagnetic layer is antiferromagnetically coupled to the third ferromagnetic layer, and
a magnetization direction of the third ferromagnetic layer is fixed to a direction antiparallel to a magnetization direction of the first ferromagnetic layer.

17. The device of claim 15, wherein
a stray field from the third ferromagnetic layer configured to reduce an influence of a stray field from the first ferromagnetic layer on a magnetization direction of the second ferromagnetic layer.

18. The device of claim 1, wherein
the first ferromagnetic layer contains at least one element selected from a group consisting of iron (Fe), cobalt (Co), and nickel (Ni),
the first nonmagnetic layer contains an oxide of at least one element or compound selected from a group consisting of magnesium (Mg), aluminum (Al), zinc (Zn), titanium (Ti), and lanthanum-strontium-manganese (LSM), and
the second ferromagnetic layer contains at least one element selected from a group consisting of iron (Fe), cobalt (Co), and nickel (Ni).

19. The device of claim 18, wherein
each of the first ferromagnetic layer and the second ferromagnetic layer has an axis of easy magnetization in a direction perpendicular to a film surface,
a magnetization direction of the first ferromagnetic layer is fixed, and
a magnetization direction of the second ferromagnetic layer is more easily reversed than the magnetization direction of the first ferromagnetic layer.

20. The device of claim 1, further comprising:
a first conductive layer provided to extend in a first direction;
a second conductive layer provided to extend in a second direction intersecting the first direction and to be spaced apart from the first conductive layer; and
a memory cell provided in a columnar shape between the first conductive layer and the second conductive layer, wherein
the memory cell includes the first ferromagnetic layer, the first nonmagnetic layer, the second ferromagnetic layer, the oxide layer, and the second nonmagnetic layer.
